(19) United States
(12) Patent Application Publication
(10) Pub. No.: US 2019/0099775 A1
(43) Pub. Date: Apr. 4, 2019

(54) Roll-to-Roll Deposition Apparatus and Roll-to-Roll Deposition Method

(71) Applicant: ULVAC, INC., Chigasaki-shi, Kanagawa (JP)

(72) Inventors: JUNICHI SAKAMOTO, Chigasaki-shi, Kanagawa (JP); KAZUYA SAITO, Chigasaki-shi, Kanagawa (JP); JUNYA KIYOTA, Chigasaki-shi, Kanagawa (JP); MASAKI TAKEI, Chigasaki-shi, Kanagawa (JP); AKIHIRO YOKOYAMA, Chigasaki-shi, Kanagawa (JP)

(21) Appl. No.: 16/085,875

(22) PCT Filed: Nov. 22, 2017
(86) PCT No.: PCT/JP2017/042071

§ 371 Date: Sep. 17, 2018

(30) Foreign Application Priority Data
Jan. 5, 2017 (JP) 2017-000592

(51) Int. Cl. B05C 1/08; B05D 1/28; C23C 14/56; B41M 1/28

(52) U.S. Cl. CPC B05C 1/0821; B05D 1/28; B41M 1/28; C23C 14/56; B05C 1/083

(57) ABSTRACT

[Object] To reduce heat damage to a film when a lithium layer is formed on the film by using a roll-to-roll system.

[Solving Means] A roll-to-roll deposition apparatus includes a vacuum chamber, a film travel mechanism, a lithium source, and a first roller. The vacuum chamber is capable of maintaining a reduced-pressure state. The film travel mechanism is capable of causing a film to travel inside the vacuum chamber. The lithium source is capable of making lithium melt inside the vacuum chamber. The first roller is disposed between a deposition surface of the film and the lithium source. The first roller has a transfer pattern that receives the molten lithium from the lithium source. The first roller transfers a pattern of a lithium layer corresponding to the transfer pattern to the deposition surface while being rotated.

### TECHNICAL FIELD

The present invention relates to a roll-to-roll deposition apparatus and a roll-to-roll deposition method.

### BACKGROUND

As a type of roll-to-roll deposition apparatus, there is an apparatus that deposits metal on the film while paying out a film from a payout roller, and takes up the film by a take-up roller.

In the roll-to-roll deposition apparatus of this type, a metal deposition source is disposed on the way between the payout roller and the take-up roller so as to face the film (e.g., see Patent Literature 1). When metal evaporating from the metal deposition source adheres to the film, the phase of the metal changes from gas to solid on the film, and the solid-state metal layer is formed on the film.

### CITATION LIST

### Patent Literature

Patent Literature 1: WO2008/018297

### DISCLOSURE OF INVENTION

### Technical Problem

However, if the metal layer formed on the film is a lithium layer, lithium releases large latent heat during phase change from gas to solid, and the film is susceptible to heat damage due to this latent heat. This latent heat becomes larger as the thickness of the lithium layer formed on the film becomes larger. Thus, the film becomes more susceptible to heat damage as the thickness of the lithium layer becomes larger.

In view of the above-mentioned circumstances, it is an object of the present invention to provide a roll-to-roll deposition apparatus and a roll-to-roll deposition method, by which heat damage to a film is reduced even if a lithium layer is formed on the film by using a roll-to-roll system.

### Solution to Problem

In order to accomplish the above-mentioned object, a roll-to-roll deposition apparatus according to an embodiment of the present invention includes a vacuum chamber, a film travel mechanism, a lithium source, and a first roller. The vacuum chamber is capable of maintaining a reduced-pressure state. The film travel mechanism is capable of causing a film to travel inside the vacuum chamber. The lithium source is capable of making lithium melt inside the vacuum chamber. The first roller is disposed between a deposition surface of the film and the lithium source. The first roller has a transfer pattern that receives the molten lithium from the lithium source. The first roller transfers a pattern of a lithium layer corresponding to the transfer pattern to the deposition surface while rotating.

In accordance with such a roll-to-roll deposition apparatus, the molten lithium is received by the first roller having the transfer pattern, and the pattern of the lithium layer is directly transferred from the first roller to the deposition surface of the film. That is, the lithium layer is patterned onto the deposition surface of the film by application, not by vacuum deposition. With this, heat damage to the film is reduced.

The roll-to-roll deposition apparatus may further include a second roller that faces the first roller via the film.

In accordance with such a roll-to-roll deposition apparatus, the first roller is held in contact with the second roller via the film. With this, the pattern of the lithium layer is more clearly transferred from the first roller to the deposition surface of the film.

In the roll-to-roll deposition apparatus, the lithium source may include a melting container and a doctor blade. The melting container stores the molten lithium. A molten surface of the lithium is held in contact with the first roller. The doctor blade controls a thickness of the lithium supplied from the melting container to the first roller.

In accordance with such a roll-to-roll deposition apparatus, the thickness of the lithium supplied from the melting container to the first roller is reliably controlled by the doctor blade.

In the roll-to-roll deposition apparatus, the lithium source may include a third roller, a melting container, and a doctor blade. The third roller faces the first roller. The melting container stores the molten lithium. A molten surface of the lithium is held in contact with the third roller. The doctor blade controls a thickness of the lithium supplied from the melting container to the third roller.

In accordance with such a roll-to-roll deposition apparatus, the thickness of the lithium supplied from the melting container to the first roller is more reliably controlled by the doctor blade and the third roller.

In the roll-to-roll deposition apparatus, the lithium source may include a third roller, a fourth roller, and a melting container. The third roller faces the first roller. The fourth roller faces the third roller. The melting container stores the molten lithium. A molten surface of the lithium is held in contact with the fourth roller.

In accordance with such a roll-to-roll deposition apparatus, the thickness of the lithium supplied from the melting container to the first roller is more reliably controlled by the third roller and the fourth roller.

The roll-to-roll deposition apparatus may further include a pretreatment mechanism that cleans the deposition surface of the film, the pretreatment mechanism being placed upstream from the first roller.

In accordance with such a roll-to-roll deposition apparatus, the deposition surface of the film is cleaned before the pattern of the lithium layer is transferred from the first roller to the deposition surface of the film. With this, the adhesion force between the lithium layer and the film increases.

The roll-to-roll deposition apparatus may further include a protection layer-forming mechanism that forms a protection layer on a surface of the lithium layer, the protection layer-forming mechanism being placed downstream from the first roller.

In accordance with such a roll-to-roll deposition apparatus, the lithium layer is protected by the protection layer after the pattern of the lithium layer is transferred from the first roller to the deposition surface of the film.

The roll-to-roll deposition apparatus may further include a separator by which the protection layer-forming mechanism is isolated inside the vacuum chamber.

In accordance with such a roll-to-roll deposition apparatus, the protection layer-forming mechanism is isolated by the separator, and ingredients of the protection layer are barely mixed into the lithium layer.

Further, in order to accomplish the above-mentioned object, a roll-to-roll deposition method according to an embodiment of the present invention includes traveling a film inside a vacuum chamber capable of maintaining a reduced-pressure state. Molten lithium is supplied to a first roller on which a transfer pattern is formed. The first roller is rotated while holding a pattern of a lithium layer corresponding to the transfer pattern in contact with a deposition surface of the film, such that the pattern of the lithium layer is transferred to the deposition surface.

In accordance with such a roll-to-roll deposition method, the molten lithium is supplied to the first roller having the transfer pattern, and the pattern of the lithium layer is directly transferred from the first roller to the deposition surface of the film. That is, the lithium layer is patterned onto the deposition surface of the film by application, not by vacuum deposition. With this, heat damage to the film is reduced.

### Advantageous Effects of Invention

As described above, in accordance with the present invention, it is possible to provide a roll-to-roll deposition apparatus and a roll-to-roll deposition method, by which heat damage to a film is reduced even if a lithium layer is formed on the film by using a roll-to-roll system.

### BRIEF DESCRIPTION OF DRAWINGS

FIG. 1 A schematic structural diagram of a roll-to-roll deposition apparatus according to a first embodiment.

FIG. 2 A schematic flowchart showing a roll-to-roll deposition method according to the first embodiment.

FIG. 3 A schematic structural diagram showing an operation of the roll-to-roll deposition apparatus according to the first embodiment.

FIG. 4 A schematic structural diagram of a roll-to-roll deposition apparatus according to a second embodiment.

FIG. 5 A schematic structural diagram of a roll-to-roll deposition apparatus according to a third embodiment.

FIG. 6 A schematic structural diagram showing an operation of the roll-to-roll deposition apparatus according to the third embodiment.

FIG. 7 A schematic structural diagram of a part of a roll-to-roll deposition apparatus according to a fourth embodiment.

### MODE(S) FOR CARRYING OUT THE INVENTION

Hereinafter, embodiments of the present invention will be described with reference to the drawings. Some of the figures have X-, Y-, and Z-axis coordinates.

### First Embodiment

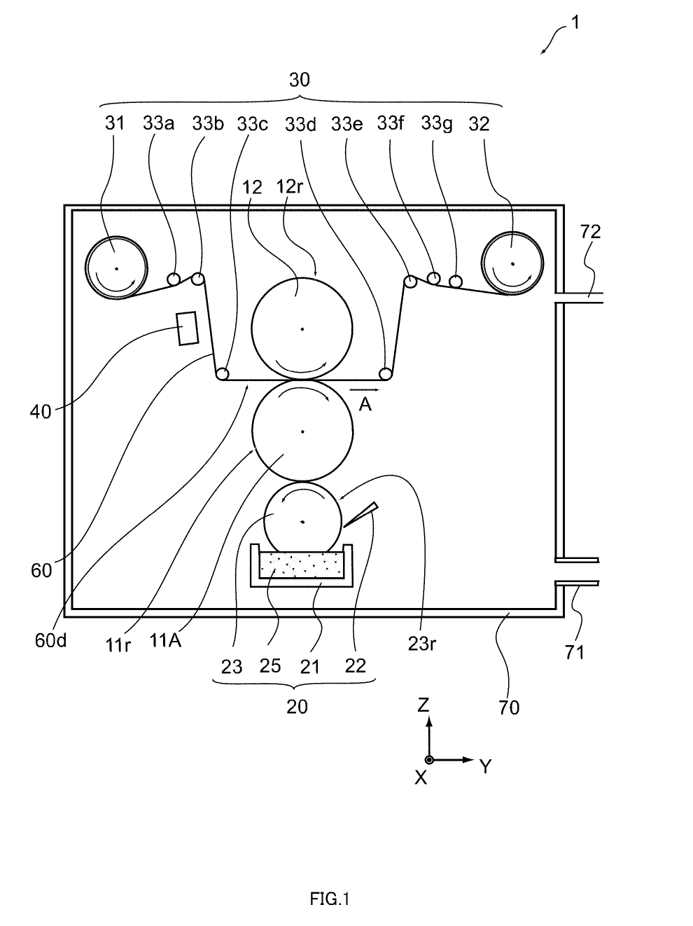

FIG. 1 is a schematic structural diagram of a roll-to-roll deposition apparatus according to a first embodiment.

A roll-to-roll deposition apparatus 1 shown in FIG. 1 is a roll-to-roll deposition apparatus capable of coating a film 60 with a metal layer (e.g., lithium layer) while causing the film 60 to travel. The roll-to-roll deposition apparatus 1 includes a first roller 11A, a lithium source 20, a film travel mechanism 30, and a vacuum chamber 70. In addition, the roll-to-roll deposition apparatus 1 includes a second roller 12, a pretreatment mechanism 40, a gas discharge mechanism 71, and a gas supply mechanism 72.

The first roller 11A is a tubular member containing metal such as stainless steel, iron, and aluminum. The first roller 11A is disposed between the film 60 and the lithium source 20. The first roller 11A faces a deposition surface 60d of the film 60. For example, a roller surface 11r of the first roller 11A is held in contact with the deposition surface 60d of the film 60. Further, a transfer pattern is formed on the roller surface 11r. The transfer pattern is, for example, a convex pattern such as a bank-shaped pattern and a hill-shaped pattern. Therefore, the first roller 11A can also be called plate cylinder in relief printing.

The first roller 11A is rotatable about its center axis. For example, a rotary drive mechanism that rotationally drives the first roller 11A may be provided outside the roll-to-roll deposition apparatus 1. Alternatively, the first roller 11A itself may include the rotary drive mechanism.

For example, with the film 60 traveling in an arrow-A direction, the first roller 11A faced to the film 60 is rotated in the clockwise direction. At this time, the movement velocity (tangential velocity) of the roller surface 11r is set to be equal to the travel velocity of the film 60, for example. With this, after a lithium pattern is formed on the roller surface 11r, this lithium pattern is transferred to the deposition surface 60d of the film 60 without position shift.

Further, in this embodiment, a temperature control mechanism such as a temperature control medium circulation system may be provided inside the first roller 11A. With this temperature control mechanism, control is performed as appropriate such that, for example, the temperature of the roller surface 11r can be equal to or higher than the melting point of lithium.

The second roller (back-up roller) 12 is a tubular member containing metal such as stainless steel, iron, and aluminum. The second roller 12 faces the first roller 11A via the film 60. A roller surface 12r of the second roller 12 is held in contact with a back surface of the film 60 (surface opposite to the deposition surface 60d). The transfer pattern is not formed on the roller surface 12r.

The second roller 12 is rotatable about its center axis. For example, the second roller 12 held in contact with the film 60 is rotated in the counter-clockwise direction due to the travel of the film 60. Alternatively, a rotary drive mechanism that rotationally drives the second roller 12 may be provided outside the roll-to-roll deposition apparatus 1. Alternatively, the second roller 12 itself may include the rotary drive mechanism. In this case, the second roller 12 is rotated by the rotary drive mechanism in the counter-clockwise direction.

Further, in this embodiment, a temperature control mechanism such as a temperature control medium circulation system may be provided inside the second roller 12. With this temperature control mechanism, control is performed as appropriate such that, for example, the temperature of the roller surface 12r can be equal to or higher than the melting point of lithium.

The lithium source 20 includes a melting container 21, a doctor blade 22, and a third roller 23. The lithium source 20 is disposed so as to face the first roller 11A. The melting container 21 stores molten lithium (Li) 25. For example, during operation of the roll-to-roll deposition apparatus 1, the lithium 25 is molten in the melting container 21 by using a technique such as resistance heating, induction heating, and electron beam heating.

The third roller 23 is a tubular member, and is a so-called anilox roller. The first roller 11A is located between the third roller 23 and the second roller 12. For example, the third roller 23, the first roller 11A, and the second roller 12 are arranged in the stated order from the top to the bottom of the roll-to-roll deposition apparatus 1. The third roller 23 faces the first roller 11A. A roller surface 23r of the third roller 23 is formed of a layer (e.g., chromium (Cr) layer or ceramic layer) having a plurality of holes, for example.

The roller surface 23r of the third roller 23 is held in contact with the roller surface 11r of the first roller 11A. In addition, in the example of FIG. 1, the roller surface 23r of the third roller 23 is held in contact with the molten surface of the lithium 25 in the melting container 21. That is, a part of the third roller 23 is immersed in the molten lithium 25.

The third roller 23 is rotatable about its center axis. For example, the third roller 23 held in contact with the first roller 11A is rotated in the counter-clockwise direction by rotation of the first roller 11A. Alternatively, a rotary drive mechanism that rotationally drives the third roller 23 may be provided outside the roll-to-roll deposition apparatus 1. Alternatively, the third roller 23 itself may include the rotary drive mechanism. In this case, the third roller 23 is rotated by the rotary drive mechanism in the counter-clockwise direction.

Further, in this embodiment, a distance control mechanism that changes a relative distance between the third roller 23 and the melting container 21 may be provided outside the roll-to-roll deposition apparatus 1. With this distance control mechanism, the amount of lithium 25 that adheres to the roller surface 23r can be changed.

When the third roller 23 is rotated with the third roller 23 immersed in the molten lithium 25, the lithium 25 in the melting container 21 is upwardly moved along the roller surface 23r. With this, the molten lithium 25 is supplied from the melting container 21 to the entire area of the roller surface 23r of the third roller 23. Further, in the roll-to-roll deposition apparatus 1, the doctor blade 22 is provided near the roller surface 23r of the third roller 23.

Due to the provision of the doctor blade 22, the thickness of the lithium 25 on the roller surface 23r is accurately adjusted. For example, the thickness of the lithium 25 on the roller surface 23r is adjusted so as to be substantially uniform. With this, the supply amount of lithium 25 is constant on the first roller 11A supplied with the lithium 25 from the third roller 23. Then, the lithium 25 on the roller surface 23r extends over the roller surface 11r of the first roller 11A held in contact with the lithium 25 on the roller surface 23r. In this manner, a constant amount of lithium 25 is supplied from the melting container 21 to the roller surface 11r of the first roller 11A via the third roller 23.

In this case, the supply amount of lithium 25 supplied to the roller surface 23r by the doctor blade 22 is constant. Therefore, the supply amount of lithium 25 supplied to the roller surface 11r of the first roller 11A is also constant. With this, the thickness of the lithium 25 on the roller surface 11r is uniform.

Further, in this embodiment, a temperature control mechanism such as a temperature control medium circulation system may be provided inside the third roller 23. With this temperature control mechanism, control is performed as appropriate such that, for example, the temperature of the roller surface 23r can be equal to or higher than the melting point of lithium. The film travel mechanism 30 includes a payout roller 31, a take-up roller 32, and guide rollers 33a, 33b, 33c, 33d, 33e, 33f, and 33g. A rotary drive mechanism that rotationally drives the payout roller 31 and the take-up roller 32 is provided outside the roll-to-roll deposition apparatus 1. Alternatively, each of the payout roller 31 and the take-up roller 32 may include the rotary drive mechanism.

The film 60 is placed in the roll-to-roll deposition apparatus 1, nipped between the first roller 11A and the second roller 12. The deposition surface 60d of the film 60 faces the first roller 11A. The film 60 is wound around the payout roller 31 in advance and paid out from the payout roller 31.

The film 60 paid out from the payout roller 31 is traveling while being supported by the guide rollers 33a, 33b, and 33c, and is moved between the first roller 11A and the second roller 12 while changing the travel direction at each of the guide rollers 33a, 33b, and 33c. In addition, the film 60 is traveling while being supported by the guide rollers 33d, 33e, 33f, and 33g, and continuously taken up by the take-up roller 32 while changing the travel direction at each of the guide rollers 33d, 33e, 33f, and 33g.

The film 60 is a long film cut at a predetermined width. The film 60 includes at least any of copper, aluminum, nickel, stainless steel, and resin. Regarding the resin, an OPP (oriented polypropylene) film, a PET (polyethylene terephthalate) film, or a PPS (polyphenylene sulfide) film is used, for example.

The pretreatment mechanism 40 is placed upstream from the first roller 11A. The pretreatment mechanism 40 cleans the deposition surface 60d of the film 60. For example, the pretreatment mechanism 40 is capable of generating plasma of inert gas (Ar, He, etc.), nitrogen (N₂), oxygen (O₂), and the like. When the deposition surface 60d of the film 60 is exposed to this plasma, an oil film, a natural oxidation film, and the like adhering to the deposition surface 60d are removed. With this, the adhesion force of the lithium layer formed on the deposition surface 60d increases.

The first roller 11A, the second roller 12, the lithium source 20, the film travel mechanism 30, the pretreatment mechanism 40, and the film 60 described above are stored in the vacuum chamber 70. The vacuum chamber 70 is capable of maintaining a reduced-pressure state. For example, the interior of the vacuum chamber 70 is maintained at a predetermined degree of vacuum by the gas discharge mechanism 71 connected to a vacuum pumping system (not shown) such as a vacuum pump. With this, an environment where the dew point of lithium becomes −50° C. or less is easily formed, and the melting state of lithium can be stably kept inside the vacuum chamber 70. Reaction of lithium having a much higher reactivity is suppressed.

Alternatively, the gas supply mechanism 72 may supply at least any of gases such as dry air, inert gas (Ar, He, etc.), carbon dioxide (CO₂), nitrogen, and the like into the vacuum chamber 70. By introducing these gases into the vacuum chamber 70, reaction of lithium having a high reactivity is suppressed.

Further, in this embodiment, at least any of indium (In), zinc (Zn), tin (Sn), gallium (Ga), bismuth (Bi), natrium (Na), kalium (K), and alloy having a melting point of 400° C. or less may be stored in the melting container 21 in addition to lithium.

### Operation of Roll-to-Roll Deposition Apparatus

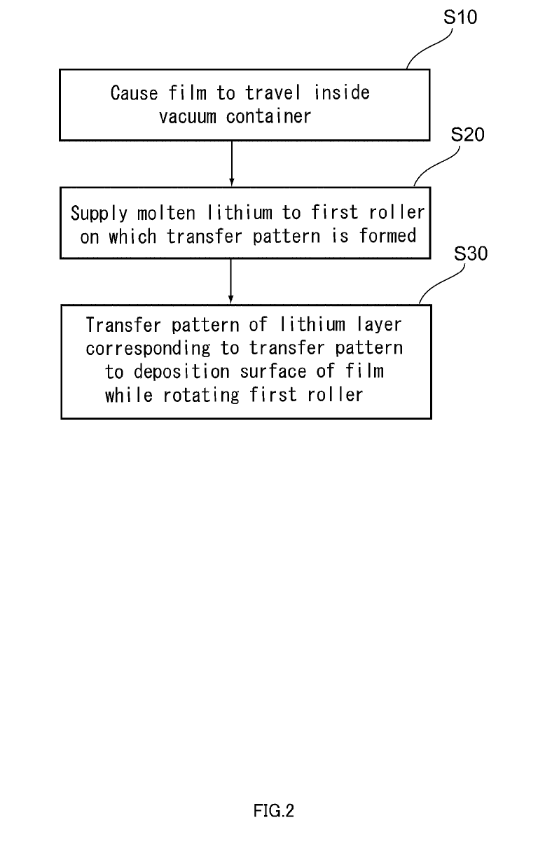

FIG. 2 is a schematic flowchart showing a roll-to-roll deposition method according to the first embodiment.

In the roll-to-roll deposition method according to the first embodiment, the film travel mechanism 30 causes the film 60 to travel inside the vacuum chamber 70 capable of maintaining a reduced-pressure state, for example (Step S10).

Next, the molten lithium 25 is supplied from the lithium source 20 to the first roller 11A on which a transfer pattern is formed (Step S20).

Next, the pattern of the lithium layer corresponding to the transfer pattern is transferred to the deposition surface by holding the pattern of the lithium layer corresponding to the transfer pattern in contact with the deposition surface 60d of the film 60 while rotating the first roller 11A (Step S30).

In accordance with such a roll-to-roll deposition method, the molten lithium 25 is supplied to the first roller 11A having the transfer pattern, and the pattern of the lithium layer is directly transferred from the first roller 11A to the deposition surface 60d of the film 60. That is, the lithium layer is patterned onto the deposition surface 60d of the film 60 by application, not by vacuum deposition. With this, heat damage to the film 60 is reduced.

A specific operation of the roll-to-roll deposition apparatus 1 will be described.

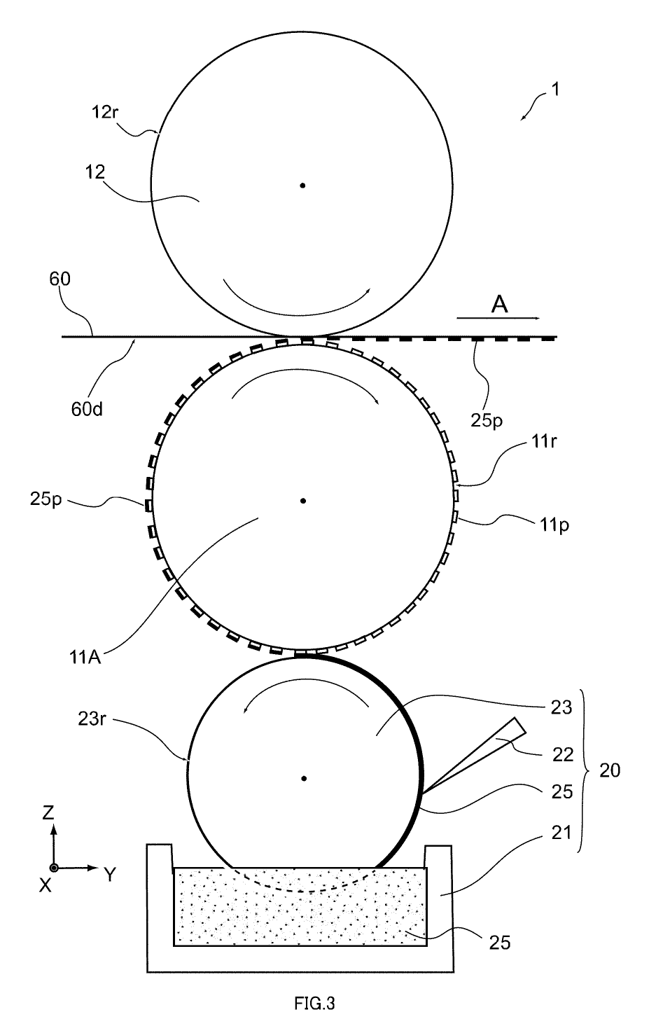

FIG. 3 is a schematic structural diagram showing an operation of the roll-to-roll deposition apparatus according to the first embodiment.

As shown in FIG. 3, the film 60 travels between the first roller 11A and the second roller 12 in the arrow-A direction. Here, a convex transfer pattern 11p is formed on the roller surface 11r of the first roller 11A. The material of the transfer pattern 11p includes, for example, an elastic material such as a rubber, an organic or inorganic resin, and the like. The reduced-pressure state is maintained inside the vacuum chamber 70. At least any of gases such as the dry air, inert gas (Ar, He, etc.), carbon dioxide (CO₂), nitrogen, and the like may be supplied into the vacuum chamber 70. The pressure inside the vacuum chamber 70 is, for example, set to 1×10⁻⁵ Pa or more and 1×10⁻² Pa or less. Further, the deposition surface 60d of the film 60 is subjected to pretreatment (cleaning) by the pretreatment mechanism 40.

Next, the molten lithium 25 is supplied from the lithium source 20 onto the transfer pattern 11p of the first roller 11A.

For example, a part of the roller surface 23r of the third roller 23 is immersed in the molten surface of the lithium 25. In addition, the temperature of the roller surface 23r of the third roller 23 is controlled by the temperature control mechanism to be equal to or higher than the melting point (180° C.) of lithium. With this, also when the third roller 23 is rotated in the counter-clockwise direction and the roller surface 23r is thus separated from the molten surface of the lithium 25, the lithium 25 is kept wet in the melting state on the roller surface 23r. Further, the thickness of the lithium 25 on the roller surface 23r is accurately adjusted by the doctor blade 22.

Next, the first roller 11A is rotated in the clockwise direction with the rotation of the third roller 23. In addition, the first roller 11A is held in contact with the third roller 23. With this, the transfer pattern 11p of the first roller 11A gets wet with the molten lithium 25, and the roller surface 11r receives the molten lithium 25 from the roller surface 23r. That is, the molten lithium 25 is formed on the transfer pattern 11p, and a pattern 25p of the lithium 25 corresponding to the transfer pattern 11p is formed on the roller surface 11r.

Here, the temperature of the roller surface 11r of the first roller 11A is controlled by the temperature control mechanism to be equal to or higher than the melting point (180° C.) of lithium. With this, also when the first roller 11A is rotated and the roller surface 11r is thus separated from the third roller 23, the lithium 25 is kept wet in the melting state on the transfer pattern 11p.

The film 60 is traveling between the first roller 11A and the second roller 12 with the rotation of the first roller 11A and the second roller 12. Here, the first roller 11A is held in contact with the deposition surface 60d of the film 60. With this, the pattern 25p is also held in contact with the deposition surface 60d of the film 60, and the pattern 25p is transferred from the transfer pattern 11p to the deposition surface 60d of the film 60.

After that, the pattern 25p of the lithium 25 on the deposition surface 60d is naturally cooled, and the pattern 25p of the lithium layer is formed on the deposition surface 60d of the film 60. The thickness of the lithium layer formed on the deposition surface 60d is, for example, 0.5 μm or more and 50 μm or less. Note that the pattern 25p of the lithium layer may be formed on both sides of the film 60.

In this manner, in this embodiment, the molten lithium 25 is received by the first roller 11A having the transfer pattern 11p. After that, the pattern 25p of the lithium layer is directly transferred from the first roller 11A to the deposition surface 60d of the film 60.

In this embodiment, the lithium pattern 25p is formed on the deposition surface 60d of the film 60 by phase change from liquid to solid, not by phase change from gas to solid. With this, the latent heat from lithium to the film 60 is further reduced, and heat damage to the film 60 is greatly reduced. Even if the pattern of the lithium layer having a relatively large thickness, for example, a thickness of 0.5 μm or more and 50 μm or less is formed on the deposition surface 60d of the film 60, heat damage to the film 60 is reduced.

Further, in this embodiment, the first roller 11A is provided with the transfer pattern 11p, and the lithium pattern 25p is formed on the film 60 from the first roller 11A directly. With this, it is unnecessary to use a dedicated mask for forming the lithium pattern on the film 60. With this, regular maintenance work of exchanging a mask to which lithium has adhered. In addition, it is unnecessary to use a complicated mechanism for taking up and paying out the mask together with the film 60 and a complicated mechanism for positioning the mask.

Further, in this embodiment, the lithium layer is patterned onto the film 60 in a reduced-pressure atmosphere. With this, the melting state of lithium can be stably maintained inside the melting container 21, and an environment where reaction of lithium having a much higher reactivity is suppressed is easily formed. Further, also if the lithium layer is patterned onto the film 60 in an inert gas atmosphere, reaction of lithium having a high reactivity is suppressed.

Further, in this embodiment, the film 60 is nipped by the first roller 11 and the second roller 12 from upper and lower sides and the transfer pattern 11p is transferred to the film 60 while the film 60 is moved in a horizontal direction. With this, the pattern 25p immediately after transferring to the film 60 is barely displaced in an in-plane direction of the film 60.

### Second Embodiment

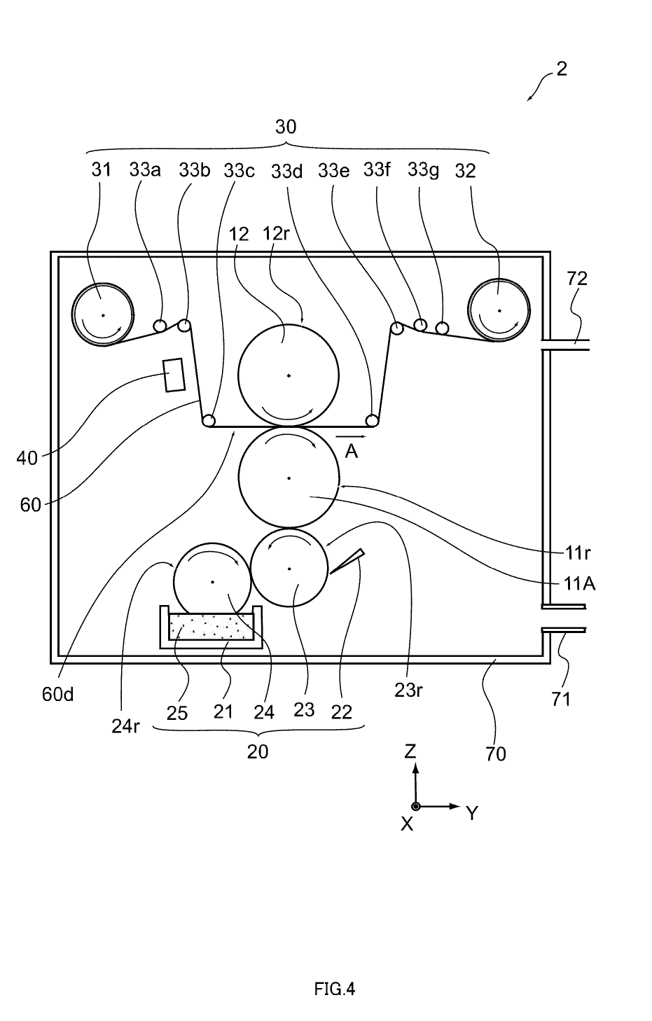

FIG. 4 is a schematic structural diagram of a roll-to-roll deposition apparatus according to a second embodiment.

In a roll-to-roll deposition apparatus 2 shown in FIG. 4, the lithium source 20 includes the melting container 21, the third roller 23, and a fourth roller 24 faced to the third roller 23. Although FIG. 4 illustrates the doctor blade 22 as the lithium source 20, the doctor blade 22 can be omitted depending on needs.

The fourth roller 24 is a tubular member, and is a so-called fountain roller. The third roller 23 is located between the fourth roller 24 and the first roller 11. A roller surface 24r of the fourth roller 24 is, for example, made of an elastic material such as a rubber. The roller surface 24r of the fourth roller 24 is held in contact with the roller surface 23r of the third roller 23. In addition, in the example of FIG. 4, the roller surface 24r of the fourth roller 24 is held in contact with the molten surface of the lithium 25 in the melting container 21. That is, a part of the fourth roller 24 is immersed in the molten lithium 25.

The fourth roller 24 is rotatable about its center axis. For example, the fourth roller 24 held in contact with the third roller 23 is rotated in the clockwise direction by rotation of the third roller 23. Alternatively, a rotary drive mechanism that rotationally drives the fourth roller 24 may be provided outside the roll-to-roll deposition apparatus 2. Alternatively, the fourth roller 24 itself may include the rotary drive mechanism. In this case, the fourth roller 24 is rotated by the rotary drive mechanism in the clockwise direction.

Further, in this embodiment, a distance control mechanism that changes a relative distance between the fourth roller 24 and the melting container 21 may be provided outside the roll-to-roll deposition apparatus 2. With this distance control mechanism, the amount of lithium 25 that adheres to the roller surface 24r of the fourth roller 24 can be changed.

When the fourth roller 24 is rotated with the fourth roller 24 immersed in the molten lithium 25, the lithium 25 in the melting container 21 is upwardly moved along the roller surface 24r. With this, the molten lithium 25 is supplied from the melting container 21 to the entire area of the roller surface 24r of the fourth roller 24. In addition, the lithium 25 on the roller surface 24r extends over the roller surface 23r of the third roller 23 held in contact with the lithium 25 on the roller surface 24r.

In addition, the lithium 25 on the roller surface 23r extends over the roller surface 11r of the first roller 11A held in contact with the lithium 25 on the roller surface 23r. That is, the molten lithium 25 is supplied from the melting container 21 to the roller surface 11r of the first roller 11A via the fourth roller 24 and the third roller 23.

Here, the movement velocity of the roller surface 24r may be set to be different from the movement velocity of the roller surface 23r of the third roller 23 or may be set to be equal to the movement velocity of the roller surface 23r of the third roller 23. With this velocity control, the thickness of the lithium 25 on the roller surface 23r is accurately adjusted. For example, the thickness of the lithium 25 on the roller surface 23r is adjusted so as to be substantially uniform.

Note that the direction of rotation of the fourth roller 24 is not limited to the clockwise direction, and may be the counter-clockwise direction.

Further, in this embodiment, a temperature control mechanism such as a temperature control medium circulation system may be provided inside the fourth roller 24. With this temperature control mechanism, control is performed as appropriate such that, for example, the temperature of the roller surface 24r can be equal to or higher than the melting point of lithium. Further, if the doctor blade 22 is provided near the roller surface 23r of the third roller 23, the thickness of the lithium 25 on the roller surface 23r is more accurately adjusted due to the provision of the doctor blade 22.

Also in the roll-to-roll deposition apparatus 2, the same actions and effects as the roll-to-roll deposition apparatus 1 can be provided.

### Third Embodiment

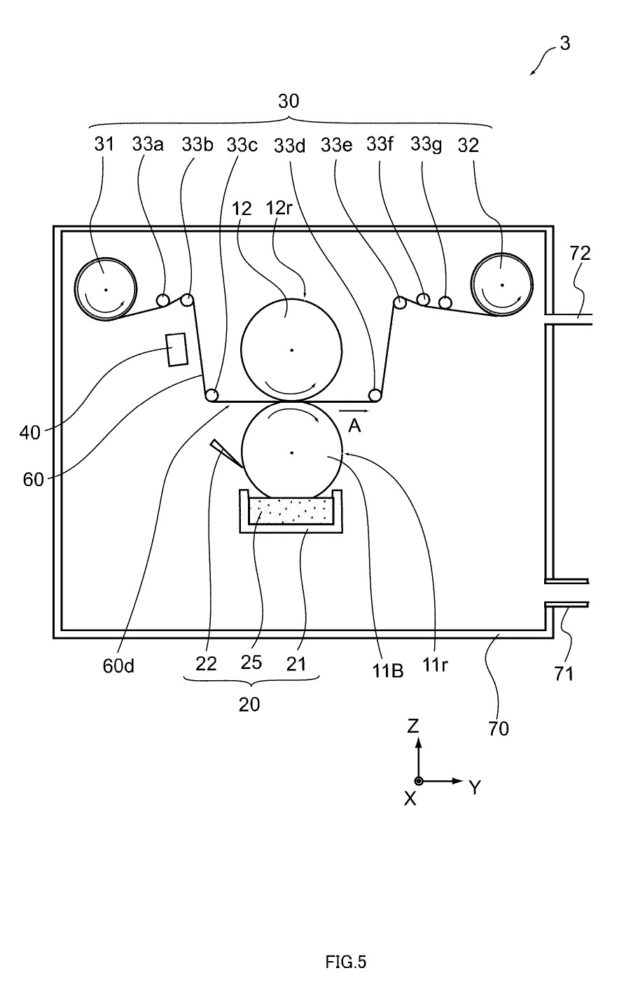

FIG. 5 is a schematic structural diagram of a roll-to-roll deposition apparatus according to a third embodiment.

A roll-to-roll deposition apparatus 3 shown in FIG. 5 includes a first roller 11B, the lithium source 20, the film travel mechanism 30, and the vacuum chamber 70. In addition, the roll-to-roll deposition apparatus 3 includes the second roller 12, the pretreatment mechanism 40, a protection layer-forming mechanism 50, the gas discharge mechanism 71, and the gas supply mechanism 72.

The first roller 11B is a tubular member containing metal such as stainless steel, iron, and aluminum. The first roller 11B is disposed between the film 60 and the lithium source 20. A roller surface 11r of the first roller 11B faces the deposition surface 60d of the film 60. For example, the roller surface 11r is held in contact with the deposition surface 60d of the film 60. In addition, in the example of FIG. 5, the roller surface 11r of the first roller 11B is held in contact with the molten surface of the lithium 25 in the melting container 21. That is, a part of the first roller 11B is immersed in the molten lithium 25. The transfer pattern is formed on the roller surface 11r. The transfer pattern is, for example, a concave pattern such as a groove-shaped pattern and a hole-shaped pattern. Therefore, the first roller 11B can also be called plate cylinder in intaglio.

The first roller 11B is rotatable about its center axis. For example, a rotary drive mechanism that rotationally drives the first roller 11B is provided outside the roll-to-roll deposition apparatus 3. Alternatively, the first roller 11B itself may include the rotary drive mechanism. For example, with the film 60 traveling in the arrow-A direction, the first roller 11B faced to the film 60 is rotated in the clockwise direction. At this time, the movement velocity of the roller surface 11r is set to be equal to the travel velocity of the film 60, for example. With this, after a lithium pattern is formed on the roller surface 11r, this lithium pattern is transferred to the deposition surface 60d of the film 60 without position shift.

Further, in this embodiment, a distance control mechanism that changes a relative distance between the first roller 11B and the melting container 21 may be provided outside the roll-to-roll deposition apparatus 3. Further, in this embodiment, a temperature control mechanism such as a temperature control medium circulation system may be provided inside the first roller 11B. With this temperature control mechanism, the temperature of the roller surface 11r is controlled as appropriate.

When the first roller 11B is rotated with the first roller 11B immersed in the molten lithium 25, the lithium 25 in the melting container 21 is upwardly moved along the roller surface 11r. With this, the molten lithium 25 is supplied from the melting container 21 to the entire area of the roller surface 11r of the first roller 11B.

Further, in the roll-to-roll deposition apparatus 3, the doctor blade 22 is provided near the roller surface 11r of the first roller 11B. Due to the provision of the doctor blade 22, the thickness of the lithium 25 in the transfer pattern is accurately adjusted. For example, the thickness of the lithium 25 in the transfer pattern is adjusted so as to be substantially uniform.

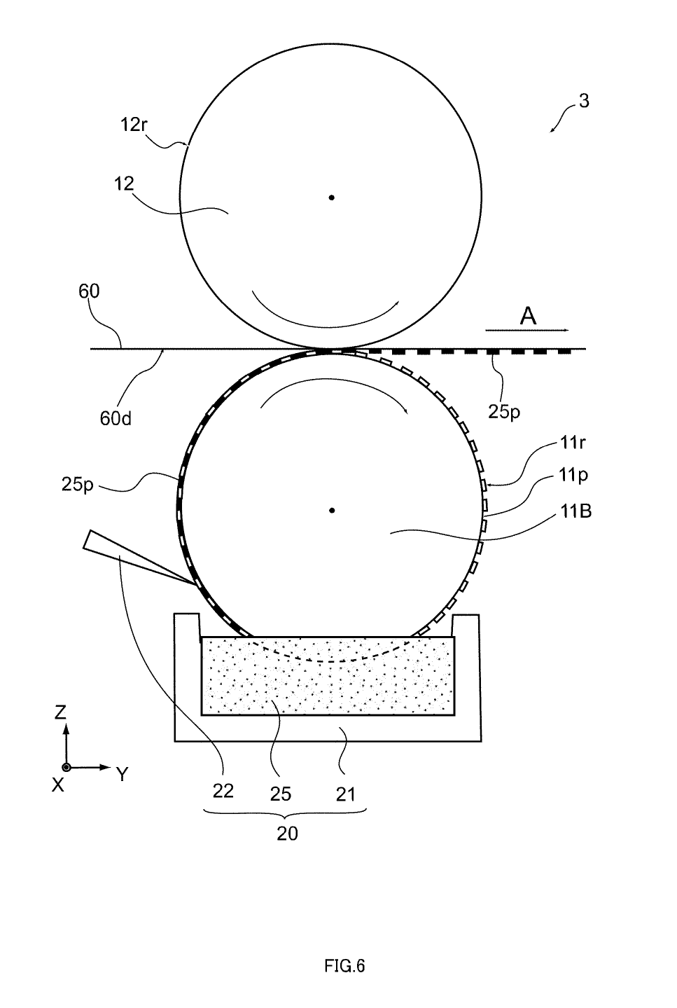

FIG. 6 is a schematic structural diagram showing an operation of the roll-to-roll deposition apparatus according to the third embodiment.

As shown in FIG. 6, a concave transfer pattern 11p is formed on the roller surface 11r of the first roller 11B. The pressure inside the vacuum chamber 70 is, for example, set to 1×10⁻⁵ Pa or more and 1×10⁻² Pa or less. Further, the deposition surface 60d of the film 60 is subjected to pretreatment by the pretreatment mechanism 40.

Next, the molten lithium 25 is supplied from the lithium source 20 to the transfer pattern 11p of the first roller 11B. For example, a part of the roller surface 11r of the first roller 11B is immersed in the molten surface of the lithium 25. In addition, the temperature of the roller surface 11r of the first roller 11B is controlled by the temperature control mechanism to be equal to or higher than the melting point of lithium.

With this, also when the first roller 11B is rotated in the clockwise direction and the roller surface 11r is thus separated from the molten surface of the lithium 25, the lithium 25 is kept wet in the melting state on the roller surface 11r. Further, the thickness of the lithium 25 on the roller surface 11r is accurately adjusted by the doctor blade 22.

The film 60 is traveling between the first roller 11B and the second roller 12 with the rotation of the first roller 11B and the second roller 12. Here, the first roller 11B is held in contact with the deposition surface 60d of the film 60. With this, the pattern 25p is also held in contact with the deposition surface 60d of the film 60, and the pattern 25p is transferred from the transfer pattern 11p to the deposition surface 60d of the film 60.

After that, the pattern 25p of the lithium 25 on the deposition surface 60d is naturally cooled, and the pattern 25p of the lithium layer is formed on the deposition surface 60d of the film 60. After that, a protection layer is further formed on the deposition surface 60d by the protection layer-forming mechanism 50 to cover the pattern 25p of the lithium layer.

Also in the roll-to-roll deposition apparatus 3, the same actions and effects as the roll-to-roll deposition apparatus 1 can be provided. In addition, in the roll-to-roll deposition apparatus 3, the transfer pattern 11p formed on the first roller 11B is the concave pattern, and hence the molten lithium 25 is efficiently received in the concave pattern. With this, the pattern 25p of the lithium layer formed on the deposition surface 60d of the film 60 becomes clearer.

### Fourth Embodiment

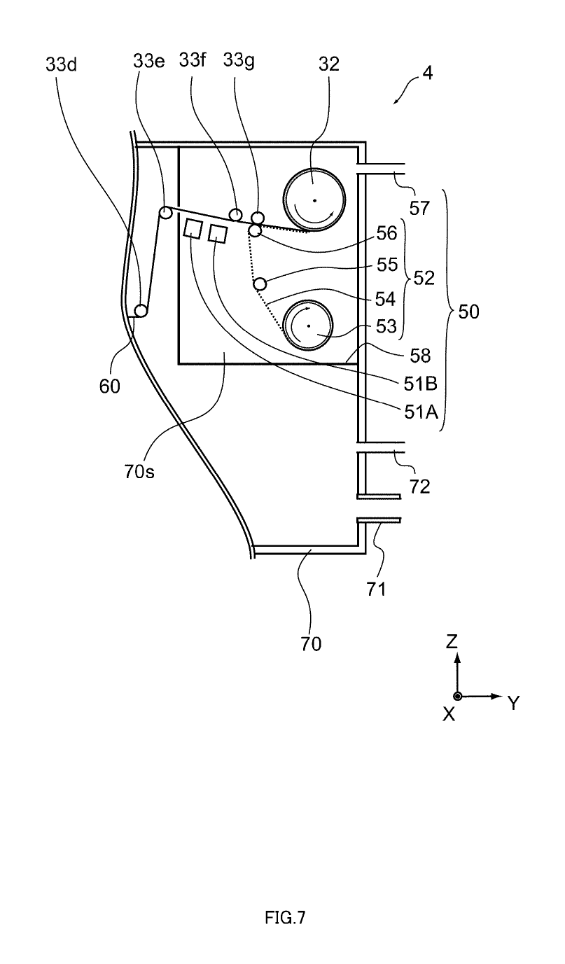

FIG. 7 is a schematic structural diagram of a part of a roll-to-roll deposition apparatus according to a fourth embodiment. FIG. 7 shows the take-up roller 32 and surroundings thereof.

A roll-to-roll deposition apparatus 4 shown in FIG. 7 further includes the protection layer-forming mechanism 50 that forms a protection layer or a protection film on the deposition surface 60d of the film 60 on which the pattern 25p of the lithium layer is formed. The protection layer-forming mechanism 50 can be combined with any of the above-mentioned roll-to-roll deposition apparatuses 1 to 3. The protection layer includes at least any of, for example, silicon oxide (SiOₓ), silicon nitride (SiNₓ), alumina oxide (AlOₓ), and the like.

The protection layer-forming mechanism 50 is placed downstream from the first roller 11A. The protection layer-forming mechanism 50 is capable of forming the protection layer or the protection film on the surface of the lithium layer after the lithium layer is formed on the film 60 by the first roller 11A.

The protection layer-forming mechanism 50 includes a protection layer-forming portion 51A, a protection layer-forming portion 51B, a protection film-forming portion 52, a gas supply mechanism 57, and a separator 58. The protection film-forming portion 52 includes a payout roller 53, a protection film 54, and guide rollers 55, 56. Each of the protection layer-forming portion 51A, the protection layer-forming portion 51B, and the protection film-forming portion 52 can be independently driven, and at least one of the protection layer-forming portion 51A, the protection layer-forming portion 51B, and the protection film-forming portion 52 can be driven.

Further, the separator 58 isolates the protection layer-forming mechanism 50 inside the vacuum chamber 70. In the example of FIG. 7, the separator 58 isolates the protection layer-forming portion 51A, the protection layer-forming portion 51B, the protection film-forming portion 52, and the gas supply mechanism 57. With this, the protection layer-forming mechanism 50 is isolated by the separator 58, and ingredients of the protection layer are barely mixed into the lithium layer.

The protection layer-forming portion 51A is capable of forming the protection layer on the deposition surface 60d of the film 60 by, for example, a film deposition technique such as sputtering, CVD (Chemical Vapor Deposition), vapor deposition. Further, by inputting elements such as silicon and aluminum from a deposition source of the protection layer-forming portion 51A into the deposition surface 60d of the film 60 while introducing gas such as oxygen, nitrogen, water, carbon monoxide, and carbon dioxide into a space 70s isolated from the gas supply mechanism 57 by the separator 58, a reaction product (protection layer) may be formed on the deposition surface 60d.

The protection layer-forming portion 51B is capable of forming the protection layer on the deposition surface 60d of the film 60 by, for example, plasma treatment or heat treatment. The protection layer may be formed on the surface of the lithium layer by, for example, introducing gas such as oxygen, nitrogen, water, carbon monoxide, and carbon dioxide into the space 70s isolated from the gas supply mechanism 57 by the separator 58 such that at least one of these gases reacts with the surface of the lithium layer. Further, in order to improve the reactivity of these gases, these gases may be transformed into plasma gases by a plasma generation means (not shown) added to the roll-to-roll deposition apparatus 4. Lithium oxide (Li₂O), lithium nitride (Li₃N), lithium carbonate (LiCOₓ), and the like are, for example, formed on the surface of the lithium layer by the protection layer-forming portion 51B.

Note that the roll-to-roll deposition apparatus 4 may include a gas discharge mechanism for discharging the gas inside the space 70s to prevent the gas inside the space 70s from leaking out of the space 70s. In this case, the pressure inside the space 70s is controlled so as to be lower than the pressure outside the space 70s. With this, for example, oxidation or the like of molten lithium stored in the melting container 21 is suppressed.

Further, the protection film-forming portion 52 is capable of bonding the protection film 54 to the deposition surface 60d of the film 60. For example, the protection film 54 is disposed so as to face the deposition surface 60d of the film 60. In addition, the protection film 54 is placed, nipped between the guide roller 33g and the guide roller 56.

The protection film 54 is wound around the payout roller 53 in advance and paid out from the payout roller 53. Supported by the guide roller 55, the protection film 54 paid out from the payout roller 53 is moved between the guide roller 33g and the guide roller 56. Then, the protection film 54 covers the deposition surface 60d of the film 60, and the protection film 54 is continuously taken up by the take-up roller 32 together with the film 60.

Hereinabove, the embodiments of the present invention have been described. The present invention is not limited to these embodiments, and various modifications can be made as a matter of course. For example, the lithium source 20 may have a mechanism of supplying the molten lithium 25 to the third roller 23 from the melting container 21 through a nozzle, a shower, or the like in the roll-to-roll deposition apparatuses 1, 2, or may have a mechanism of supplying the molten lithium 25 to the first roller 11B from the melting container 21 through a nozzle, a shower, or the like in the roll-to-roll deposition apparatus 3.

### REFERENCE SIGNS LIST

1, 2, 3, 4 roll-to-roll deposition apparatus
11A, 11B first roller
11r roller surface
11p transfer pattern
12 second roller
12r roller surface
20 lithium source
21 melting container
22 doctor blade
23 third roller
23r roller surface
24 fourth roller
24r roller surface
25 lithium
25p pattern
30 film travel mechanism
31 payout roller
32 take-up roller
33a, 33b, 33c, 33d, 33e, 33f, 33g guide roller
40 pretreatment mechanism
50 protection layer-forming mechanism
51A protection layer-forming portion
51B protection layer-forming portion
52 protection film-forming portion
53 payout roller
54 protection film
55, 56 guide roller
57 gas supply mechanism
58 separator
60 film
60d deposition surface
70 vacuum chamber
70s space
71 gas discharge mechanism
72 gas supply mechanism

1. A roll-to-roll deposition apparatus, comprising:
a vacuum chamber capable of maintaining a reduced-pressure state;
a film travel mechanism capable of causing a film to travel inside the vacuum chamber;
a lithium source capable of making lithium melt inside the vacuum chamber; and
a first roller disposed between a deposition surface of the film and the lithium source, the first roller having a transfer pattern, the transfer pattern receiving the molten lithium from the lithium source, and the first roller transferring a pattern of a lithium layer corresponding to the transfer pattern to the deposition surface while rotating.

2. The roll-to-roll deposition apparatus according to claim 1, further comprising
a second roller facing the first roller via the film.

3. The roll-to-roll deposition apparatus according to claim 1, wherein
the lithium source includes
a melting container storing the molten lithium, a surface of the molten lithium being held in contact with the first roller, and
a doctor blade controlling a thickness of the lithium supplied from the melting container to the first roller.

4. The roll-to-roll deposition apparatus according to claim 1, wherein
the lithium source includes
a third roller facing the first roller,
a melting container storing the molten lithium, a surface of the molten lithium being held in contact with the third roller, and
a doctor blade controlling a thickness of the lithium supplied from the melting container to the third roller.

5. The roll-to-roll deposition apparatus according to claim 1, wherein
the lithium source includes
a third roller facing the first roller, and
a fourth roller facing the third roller, and
a melting container storing the molten lithium, a surface of the molten lithium being held in contact with the fourth roller.

6. The roll-to-roll deposition apparatus according to claim 1, further comprising
a pretreatment mechanism cleaning the deposition surface of the film, the pretreatment mechanism being placed upstream from the first roller.

7. The roll-to-roll deposition apparatus according to claim 1, further comprising
a protection layer-forming mechanism forming a protection layer on a surface of the lithium layer, the protection layer-forming mechanism being placed downstream from the first roller.

8. The roll-to-roll deposition apparatus according to claim 7, further comprising
a separator, the protection layer-forming mechanism is isolated inside the vacuum chamber by the separator.

9. A roll-to-roll deposition method, comprising:
traveling a film inside a vacuum chamber capable of maintaining a reduced-pressure state;
supplying molten lithium to a first roller, a transfer pattern being formed on the first roller; and
contacting a pattern of a lithium layer corresponding to the transfer pattern to a deposition surface of the film to transfer the pattern of the lithium layer to the deposition surface while rotating the first roller.
